(19) United States
(12) Patent Application Publication
(10) Pub. No.: US 2012/0178231 A1
(43) Pub. Date: Jul. 12, 2012

(54) METHODS FOR FABRICATING A METAL SILICIDE LAYER AND SEMICONDUCTOR DEVICES USING THE SAME

(75) Inventors: Jin-Bum Kim, Seoul (KR); Young-Pil Kim, Hwaseong-si (KR); Hyung-Ik Lee, Suwon-si (KR); Ki-Hong Kim, Asan-si (KR); Eun-Ha Lee, Seoul (KR); Jung-Yun Won, Hwaseong-si (KR); Benayad Anass, Yongin-si (KR)

(73) Assignee: SAMSUNG ELECTRONICS CO., LTD., Suwon-si (KR)

(21) Appl. No.: 13/241,678

(22) Filed: Sep. 23, 2011

(30) Foreign Application Priority Data
Jan. 12, 2011 (KR) 10-2011-0003181

(51) Int. Cl. H01L 21/336; H01L 21/28

(52) U.S. Cl. 438/300; 438/664; 257/E21.158; 257/E21.409

(57) ABSTRACT

Methods for fabricating a metal silicide layer and for fabricating a semiconductor device having such a metal silicide layer are provided wherein, in an embodiment, the method includes the steps of forming a metal layer on a substrate, performing a first thermal process on the substrate to allow the substrate and the metal layer to react with react other to form a first pre-metal silicide layer, removing an unreacted portion of the metal layer, and performing a second thermal process on the substrate to change the first pre-metal silicide layer into a second pre-metal silicide layer and then to melt the second pre-metal silicide layer to change the second pre-metal silicide layer into a metal silicide layer.

### CROSS-REFERENCE TO RELATED APPLICATION

This application claims priority from Korean Patent Application No. 10-2011-0003181 filed on Jan. 12, 2011 in the Korean Intellectual Property Office, and all the benefits accruing therefrom under 35 U.S.C. 119, the contents of which in its entirety are herein incorporated by reference.

### FIELD

Embodiments of the present invention relate to methods for fabricating a metal silicide layer and semiconductor devices using the same.

### BACKGROUND

In order to improve the operating characteristics of a semiconductor device, efforts have been made specifically to improve the contact resistance between a silicide layer and a silicon substrate.

The contact resistance between a silicide layer and a silicon substrate varies according to a work function of the silicide and a doping concentration of the silicon substrate. In particular, a Schottky barrier height (SBH) is determined by the work function and the doping concentration, and the contact resistance is in turn determined by the SBH.

### SUMMARY

Embodiments of the present inventive concept provide methods for fabricating thermally stable metal silicide layers.

The present inventive concept also provides methods for fabricating semiconductor devices having a thermally stable metal silicide layer in accordance with the inventive concept.

These and other objects of the present invention will be described in or be apparent from the following description of the preferred embodiments.

According to a first aspect of the present inventive concept, there is provided a method for fabricating a metal silicide layer, comprising the steps of: forming a metal layer on a substrate; performing a lower-temperature thermal process on the substrate for a sufficient time and at a sufficient temperature that the substrate and the metal layer react with each other to form a first pre-metal silicide layer; removing an unreacted portion of the metal layer; and, performing a higher-temperature thermal process on the first pre-metal silicide layer that changes the first pre-metal silicide layer first into a second pre-metal silicide layer, and then melts the second pre-metal silicide layer and changes the second pre-metal silicide layer into a metal silicide layer.

In an embodiment of the first aspect of the present inventive concept, an atomic ratio of metal to silicon in the first pre-metal silicide layer is greater than 1.

In another embodiment of the first aspect of the present inventive concept, the atomic ratio of metal to silicon in the second pre-metal silicide layer and the atomic ratio of metal to silicon in the metal silicide layer are equal to or less than 1.

In another embodiment of the first aspect of the present inventive concept, the metal silicide layer is an epitaxial layer.

In another embodiment of the first aspect of the present inventive concept, the lower-temperature thermal process is carried out at a temperature lower than about 350° C.

In another embodiment of the first aspect of the present inventive concept, the higher-temperature thermal process comprises two sub-steps: a first higher-temperature thermal process sub-step carried out at a temperature of about 400° C. or higher; and, a second higher-temperature thermal process sub-step carried out at a temperature above the melting point of the second pre-metal silicide.

In another embodiment of the first aspect of the present inventive concept, a first higher-temperature thermal process sub-step and a second higher-temperature thermal process sub-step are performed in situ.

In another embodiment of the first aspect of the present inventive concept, a temperature of the second pre-metal silicide is increased to higher than 1,000° C. during a second higher-temperature thermal process sub-step.

In another embodiment of the first aspect of the present inventive concept, the lower-temperature thermal process is performed by a rapid thermal process (RTP), and a second higher-temperature thermal process sub-step is performed by flash annealing or laser annealing.

In another embodiment of the first aspect of the present inventive concept, a second higher-temperature thermal process sub-step is performed for a period of about 0.1 nano second to 10 milli seconds.

In another embodiment of the first aspect of the present inventive concept, the metal layer includes at least one member selected from the group consisting of Ni, Pt, Ti, Ru, Rh, Co, Hf, Ta, Er, Yb, W, and alloys thereof.

According to a second aspect of the present inventive concept, there is provided a method for fabricating a semiconductor device, comprising the steps of: (a) forming a first gate on a substrate; (b) implanting an impurity or impurities into source/drain regions in the substrate; (c) forming a metal layer on the source/drain regions; (d) forming a first pre-metal silicide layer by performing a lower-temperature thermal process on the substrate for a sufficient time and at a sufficient temperature that the substrate and the metal layer react to form a first pre-metal silicide layer; (e) removing an unreacted portion of the metal layer; and, (f) changing the first pre-metal silicide layer into a second pre-metal silicide layer by performing a first higher-temperature thermal process sub-step on the first pre-metal silicide layer, and then changing the second pre-metal silicide layer into a metal silicide layer by melting the second pre-metal silicide layer during a second higher-temperature thermal process sub-step.

In an embodiment of the second aspect of the present inventive concept, the method further comprises a step of performing another thermal process on the device to activate the impurity or impurities, wherein this additional thermal process is performed after step (b) but prior to step (c).

In another embodiment of the second aspect of the present inventive concept, during the second higher-temperature thermal process sub-step, the impurity or impurities implanted into the source/drain regions is/are activated.

In another embodiment of the second aspect of the present inventive concept, the method further comprises the following additional steps after step (f): (g) removing the first gate; (h) forming a high-k layer on the substrate; (i) forming a second gate on the high-k layer; and (j) performing another thermal process on the substrate to improve reliability of the high-k layer.

In another embodiment of the second aspect of the present inventive concept, during step (j) the device is heated to a temperature of 700° or higher.

In another embodiment of the second aspect of the present inventive concept, the second gate of step (i) is made of a metal.

In another embodiment of the second aspect of the present inventive concept, the method further comprises the step of forming an epitaxial layer in the source/drain regions.

In another embodiment of the second aspect of the present inventive concept, the lower-temperature thermal process is carried out at a temperature lower than about 350° C.

In another embodiment of the second aspect of the present inventive concept, the higher-temperature thermal process consists of a first higher-temperature thermal process sub-step in which the first pre-metal silicide layer is heated to a temperature of about 400° C. or higher, and a second higher-temperature thermal process sub-step in which a second pre-metal silicide layer formed by the first higher-temperature thermal process sub-step is heated to a temperature above a melting point of the second pre-metal silicide layer.

### BRIEF DESCRIPTION OF THE DRAWINGS

The above and other features and advantages of the present inventive concept will become more apparent by describing in detail preferred embodiments thereof with reference to the attached drawings in which:

FIGS. 1 to 5 are schematic cross-sectional views illustrating steps in a method of fabricating a metal silicide layer according to an aspect of the present inventive concept;

FIGS. 6 to 14 are schematic cross-sectional views illustrating steps in a method of fabricating a semiconductor device according to an aspect of the present inventive concept; and

FIGS. 15 to 20 are schematic cross-sectional views illustrating steps in a method of fabricating a semiconductor device according to another aspect of the present inventive concept.

### DETAILED DESCRIPTION OF EMBODIMENTS

Advantages and features of the present inventive concept and methods of accomplishing the same may be understood more readily by reference to the following detailed description of preferred embodiments and the accompanying drawings. The present inventive concept may, however, be embodied in many different forms and should not be construed as being limited to the embodiments set forth herein. Rather, these embodiments are provided so that this disclosure will be thorough and complete and will fully convey the concept of the invention to those skilled in the art, and the present inventive concept will only be defined by the appended claims. In the drawings, the thickness of layers and regions are exaggerated for clarity.

It will be understood that when an element or layer is referred to as being “on,” or “connected to” another element or layer, it can be directly on or connected to the other element or layer or intervening elements or layers may be present. In contrast, when an element is referred to as being “directly on” or “directly connected to” another element or layer, there are no intervening elements or layers present. Like numbers refer to like elements throughout. As used herein, the term “and/or” includes any and all combinations of one or more of the associated listed items.

Spatially relative tennis, such as “below,” “beneath,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

It will also be understood that, although the tennis first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the teens “comprises” and/or “made of,” when used in this specification, specify the presence of stated features, integers, steps, operations, elements, and/or components, but do not preclude the presence or addition of one or more other features, integers, steps, operations, elements, components, and/or groups thereof.

Embodiments described herein will be described referring to plan views and/or cross-sectional views by way of ideal schematic views of the invention. Accordingly, the exemplary views may be modified depending on manufacturing technologies and/or tolerances. Therefore, the embodiments of the invention are not limited to those shown in the views, but include modifications in configuration formed on the basis of manufacturing processes. Therefore, regions exemplified in figures have schematic properties, and shapes of regions shown in figures exemplify specific shapes of regions of elements, and therefore these descriptions should not be interpreted to limit aspects of the invention.

Unless otherwise defined, all terms (including technical and scientific terms) used herein have the same meaning as commonly understood by one of ordinary skill in the art to which this invention pertains. It will be further understood that terms, such as those defined in commonly used dictionaries, should be interpreted as having a meaning that is consistent with their meaning in the context of the relevant art and the present disclosure, and should not be interpreted in an idealized or overly formal sense unless expressly so defined herein.

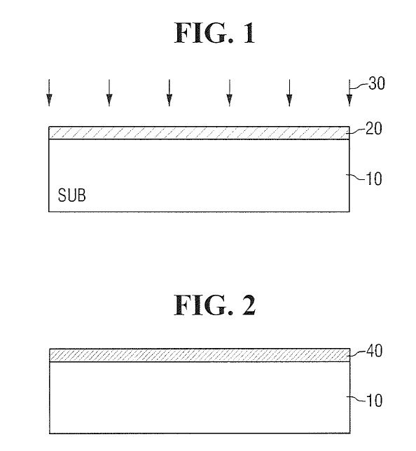

FIGS. 1 to 5 are schematic cross-sectional views illustrating steps in a method of fabricating a metal silicide layer according to an embodiment of the present inventive concept.

Referring now to FIG. 1, in a first step a metal layer 20 is formed on a substrate 10.
Specifically, the substrate 10 may include a silicon substrate, a silicon-on-insulator (SOI) substrate, a silicon germanium substrate, or the like.

The metal layer 20 may include, for example, at least one member selected from the group consisting of Ni, Pt, Ti, Ru, Rh, Co, Hf, Ta, Er, Yb, W, and alloys thereof. In a representative embodiment of the present inventive concept, Ni is used as the metal for metal layer 20. The metal layer 20 may be formed using physical vapor deposition (PVD), chemical vapor deposition (CVD), or atomic layer deposition (ALD). A thickness of the metal layer 20 is determined by taking into consideration the thickness of silicon disposed under the metal layer 20 and how much of the metal layer is likely to be consumed in the course of subsequent fabrication steps, for example in the first and second thermal processes that are performed in a later stage of the method. For example, although not shown in FIG. 1, in a case where a junction region to be used as source/drain is formed under the metal layer 20, the metal layer 20 preferably has a sufficient thickness to prevent the junction region from being fully consumed.

In the next step, as shown in FIG. 1 by the arrows 30, the substrate 10 is subjected to a first thermal process for a sufficient time and at a sufficient temperature that substrate 10 reacts with the metal layer 20 to form a first pre-metal silicide layer 40 (as seen in FIG. 2).

During the first (lower-temperature) thermal process 30, a temperature of the substrate 10 is adjusted such that an atomic ratio of metal to silicon in the first pre-metal silicide layer 40 (formed by the reaction between the substrate 10 and the metal layer 20) preferably exceeds 1. For example, in a case where Ni is used as the metal layer 20, during the first thermal process 30, the substrate 10 may be heated to a temperature lower than about 350° C. in order to form a first pre-meal silicide layer having the desired atomic ratio. In addition, the first thermal process 30 may be a rapid thermal process (RTP).

As used in this application, the term “metal-to-silicon atom ratio” means the “number of metal atoms/number of silicon atoms.” That is to say, the first pre-metal silicide layer 40 may preferably include more metal atoms than silicon atoms. For example, in a case of using Ni for the metal layer 20, the first pre-metal silicide layer 40 may include Ni₂Si. Typically only a portion of the metal layer 20 adjacent to the silicon substrate is converted by thermal process 30 to the first pre-metal silicide layer 40.

Referring next to FIG. 2, in the next step a portion of the metal layer 20 that has not reacted with the substrate 10 is removed. If a metal oxide layer is formed in the course of this step, that metal oxide layer is also removed.

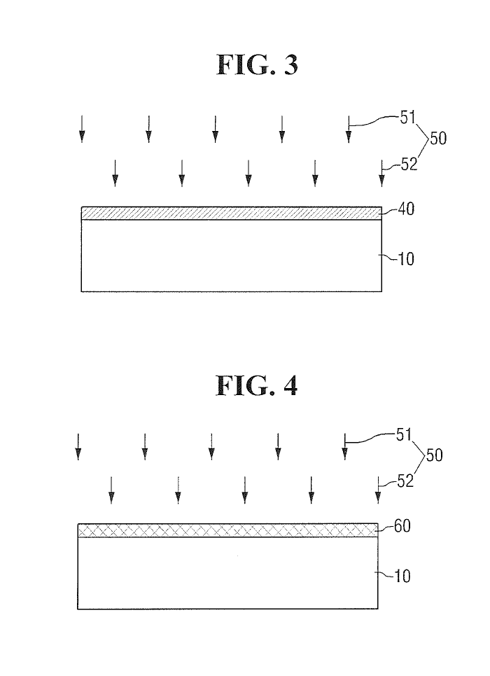

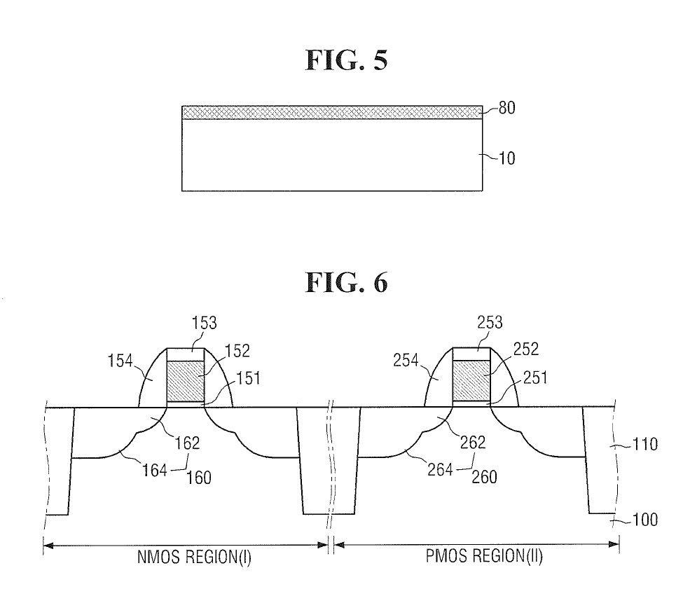

Referring next to FIGS. 3 to 5, a second (higher-temperature) thermal process 50 (as shown by the arrows 51 and 52 in FIGS. 3 and 4) is performed on the substrate 10 and the layer 40. The second thermal process 50 is performed for a sufficient time and at a sufficient temperature such that the first pre-metal silicide layer (40 of FIGS. 2 and 3) is changed, first into a second pre-metal silicide layer 60 (as seen in FIG. 4), and subsequently, by continuing the thermal process 50, into a metal silicide layer 80 (as seen in FIG. 5).

The second (higher-temperature) thermal process 50 comprises two sub-steps: a first higher-temperature thermal process sub-step 51 and a second higher-temperature thermal process sub-step 52. In the first thermal process sub-step 51, a temperature of the substrate 10 is adjusted such that the atomic ratio of metal to silicon in the second pre-metal silicide layer 60, which is formed as an intermediate product of the second thermal process 50, becomes equal to or less than 1. For example, in a case where the first pre-metal silicide layer 40 is Ni₂Si, the first thermal process sub-step 51 is performed such that the substrate 10 is heated to a temperature of about 400° C. or higher. For example, at a temperature of about 400° C. of higher, a first pre-metal silicide layer 40 of Ni₂Si may be changed to a second pre-metal silicide layer 60 of NiSi. In addition, the first thermal process sub-step 51 may be performed using RTP.

The second thermal process sub-step 52 is performed such that the second pre-metal silicide layer 60 is heated to a temperature that is above a melting point of the second pre-metal silicide layer 60, which is formed as an intermediate product of the second thermal process 50, so as to change the layer 60 into the metal silicide layer 80 (as seen in FIG. 5). For example, in a case where the second pre-metal silicide layer 60 is NiSi, the second thermal process sub-step 52 is performed such that the layer 60 is heated to a temperature of about 1,000° C. or higher. The second thermal process sub-step 52 may be performed for a time period such as about 0.1 nano second to 10 milli seconds. The second thermal process sub-step 52 may be performed, for example, using flash annealing or laser annealing.

The first higher-temperature thermal process sub-step 51 and the second higher-temperature thermal process sub-step 52 may be performed in situ. During the second thermal process sub-step 52, the substrate 10 is preferably maintained substantially at a constant temperature by performing the first thermal process sub-step 51, thereby allowing the second pre-metal silicide layer 60 to be heated to a higher temperature long enough to be sufficiently melted while preventing heat applied to layer 60 during the second thermal process sub-step 52 from also being applied to the substrate 10.

Thus, in the second thermal process 50, the first pre-metal silicide layer 40 is changed into the second pre-metal silicide layer 60, and the second pre-metal silicide layer 60 is melted and changed into the metal silicide layer 80. As noted above, an atomic ratio of metal to silicon in the second pre-metal silicide layer 60 is preferably equal to or less than 1. The metal silicide layer 80 is formed by melting the second pre-metal silicide layer 60. An atomic ratio of metal to silicon in the metal silicide layer 80 will also preferably be equal to or less than 1. The metal silicide layer 80 may be an epitaxial layer. The epitaxial metal silicide layer 80 may have a film quality similar to that of a single crystal. The metal silicide layer 80, once formed, undergoes little or no change in morphology, even under conditions of a subsequently performed thermal process at a high temperature of 700° C. or higher.

A method of fabricating a semiconductor device according to a first embodiment of the present inventive concept will now be described with reference to FIGS. 6 to 14. FIGS. 6 to 14 are schematic cross-sectional views illustrating steps in a method of fabricating a semiconductor device according to an embodiment of the present inventive concept.

Referring to FIG. 6, a substrate 100 having an NMOS region (I) where an NMOS transistor is to be formed, and a PMOS region (II), where a PMOS transistor is to be formed, is provided. Isolation regions 110 may be formed to define and separate the NMOS region (I) and the PMOS region (II).

In the NMOS region (I) there are formed the following elements: a first gate insulation layer 151, a first dummy gate 152, a first gate mask 153, a first spacer 154, and first source/drain regions 160. In the PMOS region (II) there are formed the following elements: a second gate insulation layer 251, a second dummy gate 252, a second gate mask 253, a second spacer 254, and second source/drain regions 260. The first dummy gate 152 and the second dummy gate 252 may be made of polysilicon.

The first source and drain regions 160 may include a first lightly-doped impurity region 162 and a first heavily doped impurity region 164. The second source and drain regions 260 may include a second lightly-doped impurity region 262 and a second heavily-doped impurity region 264. While the illustrated embodiment shows that the first source and drain regions 160 and the second source and drain regions 260 have a lightly diffused drain (LDD) structure, the invention is not limited thereto. For example, the first source and drain regions 160 and the second source and drain regions 260 may have a double diffused drain (DDD) structure, a mask islanded double diffused drain (MIDDD) structure, a mask LDD (MLDD) structure, or a lateral double-diffused MOS (LDMOS) structure. In the illustrated embodiment, the first source and drain regions 160 and the second source and drain regions 260 having different shapes are formed, respectively, in the NMOS region (I) and the PMOS region (II). However, the first source and drain regions 160 and the second source and drain regions 260 may also have the same general shape according to the desired use of the semiconductor device.

After the steps of implanting impurities into the first source/drain regions 160 and the second source/drain regions 260, a thermal process for activating the impurities may be performed on the semiconductor device.

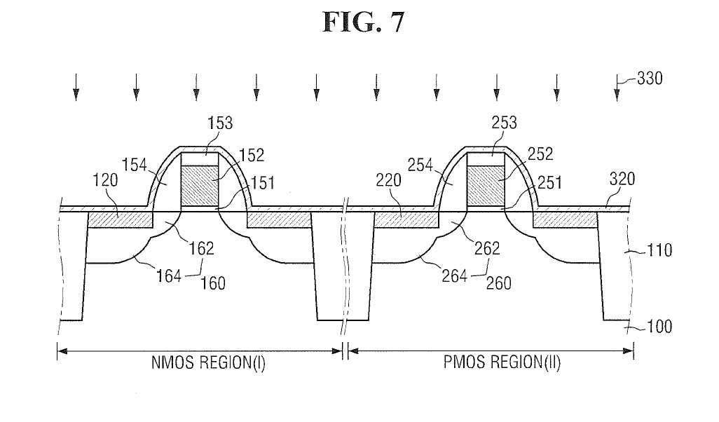

Referring now to FIG. 7, a metal layer 320 is formed on the semiconductor device of FIG. 6, which comprises the substrate 100 having the first source/drain regions 160 and the second source/drain regions 260. The metal layer 320 may include, for example, at least one member selected from the group consisting of Ni, Pt, Ti, Ru, Rh, Co, Hf, Ta, Er, Yb, W, and alloys thereof. In a particular embodiment of the present invention, Ni is used as the metal for layer 320.

Next, the device of FIG. 7 is subjected to a first (lower-temperature) thermal process (as shown by the arrows 330) for a sufficient time at a sufficient temperature that substrate 100 reacts with the metal layer 320 to form a first pre-metal silicide layer 120 in the NMOS region (I) and a third pre-metal silicide layer 220 in the PMOS region (II). In the first thermal process 330, a temperature of the substrate 100 is adjusted such that atomic ratios of metal to silicon in the first and third pre-metal silicide layers 120 and 220 are preferably greater than 1. For example, in a case where the metal layer 320 is Ni, the first thermal process 330 is performed such that the temperature of the substrate 100 is lower than about 350° C. In addition, the first thermal process 330 may be performed using RTP.

For example, in a case where the metal layer 320 is Ni, the first and third pre-metal silicide layers 120 and 220 may be, for example, Ni₂Si, thereby satisfying the atomic ratio condition.

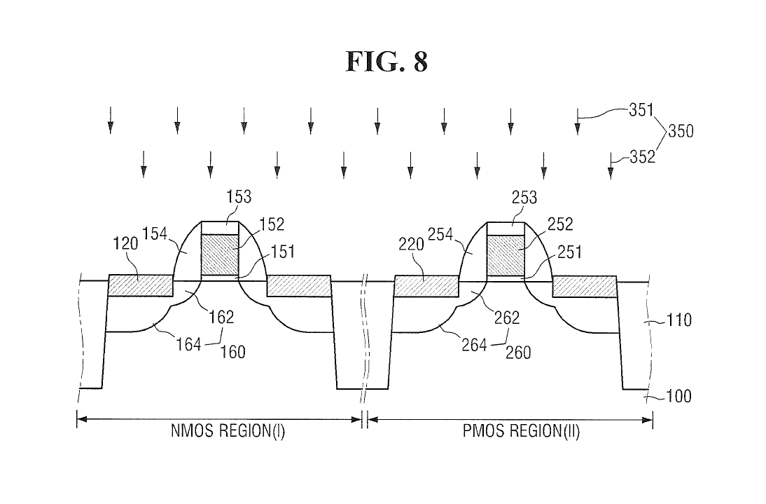

Referring next to FIGS. 8 to 10, in the next step a portion of the metal layer 320 that has not reacted with the substrate 100 is removed. If a metal oxide layer is formed in the course of this step, that metal oxide layer is also removed.

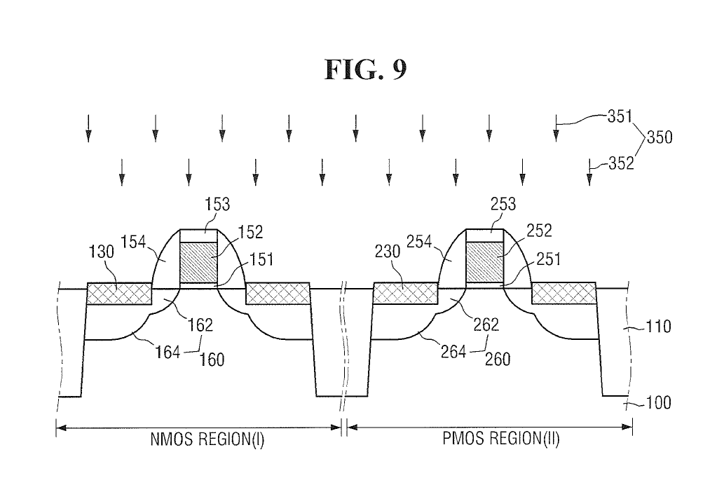

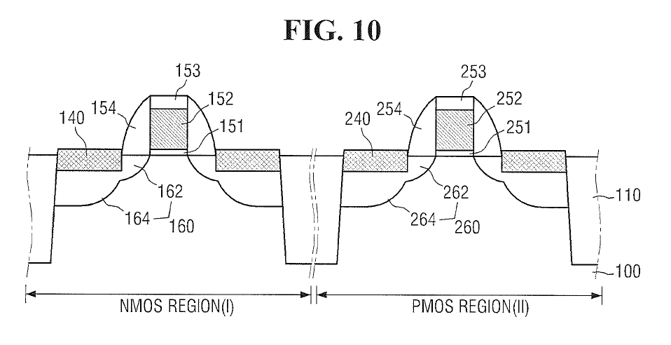

Next, a second (higher-temperature) thermal process 350 (as shown by the arrows 351 and 352 in FIGS. 8 and 9) is performed on the substrate 100 and the layers 120 and 220. The second thermal process 350 is performed for a sufficient time and at a sufficient temperature such that: (a) the first pre-metal silicide layer 120 (FIGS. 7 and 8) is changed, first into a second pre-metal silicide layer 130 (as seen in FIG. 9), and subsequently, by continuing the thermal process 350, into a first metal silicide layer 140 (as seen in FIG. 10); and, (b) the third pre-metal silicide layer 220 is changed, first into a fourth pre-metal silicide layer 230 (as seen in FIG. 9) and subsequently, by continuing the thermal process 350, into a second metal silicide layer 240 (as seen in FIG. 10).

As described above, the second (higher-temperature) thermal process 350 consists of two sub-steps: a first higher-temperature thermal process sub-step 351 and a second higher-temperature thermal process sub-step 352. In the first thermal process sub-step 351, a temperature of the substrate 100 is adjusted such that the atomic ratios of metal to silicon in the second and fourth pre-metal silicide layers 130 and 230 becomes equal to or less than 1. For example, in a case where the first and third pre-metal silicide layers 120 and 220 are Ni₂Si, the first higher-temperature thermal process sub-step 351 is performed such that the substrate 100 is heated to a temperature of about 400° C. or higher. For example, at a temperature of about 400° C. or higher, a first pre-metal silicide layer 40 of Ni₂Si may be changed to a second pre-metal silicide layer 60 of NiSi. In addition, the first thermal process sub-step 351 may be performed using RTP.

The second higher-temperature thermal process sub-step 352 is performed such that the layers 130 and 230 are heated to a temperature that is above the melting points of the second and fourth pre-metal silicide layers 130 and 230 so as to change the layers 130 and 230 into the respective metal silicide layers 140 and 240 (as seen in FIG. 10). For example, in a case where the second and fourth pre-metal silicide layers 130 and 230 are NiSi, the second thermal process sub-step 352 is performed such that the layers 130 and 230 are heated to a temperature of about 1,000° C. or higher. The second thermal process sub-step 352 may be performed for a time period such as about 0.1 nano second to 10 milli seconds. The second thermal process sub-step 352 may be performed, for example, using flash annealing or laser annealing.

The first higher-temperature thermal process sub-step 351 and the second higher-temperature thermal process sub-step 352 may be performed in situ.

Atomic ratios of metal to silicon in the second and fourth pre-metal silicide layers 130 and 230 and in the first and second metal silicide layers 140 and 240 may preferably be equal to or less than 1. The first and second metal silicide layers 140 and 240 may be epitaxial layers, and they may have a film quality similar to that of a single crystal.

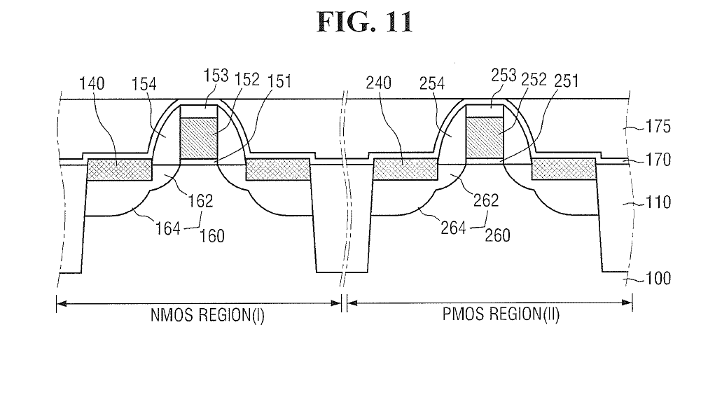

Referring next to FIG. 11, in the next step an interlayer insulation layer 175 is formed on the NMOS region (I) and the PMOS region (II) of the semiconductor device of FIG. 10. As shown in FIG. 11, before the step of forming the interlayer insulation layer 175, an etch stop layer 170 may be formed; and, the insulation layer 175 is then formed on etch stop layer 170. HeThe etch stop layer 170 and the interlayer insulation layer 175 may be formed by, for example, chemical vapor deposition (CVD). The etch stop layer 170 may be, for example, an oxide layer or a nitride layer. The interlayer insulation layer 175 may also be an oxide layer or a nitride layer.

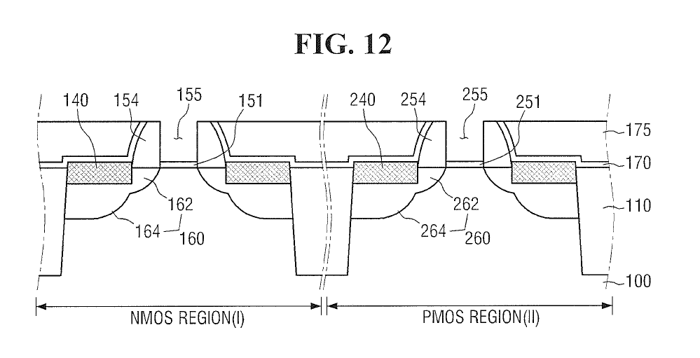

Referring now to FIGS. 11 and 12, chemical mechanical polishing (CMP) is performed on the device having the interlayer insulation layer 175 for achieving planarization. For example, the interlayer insulation layer 175 and the etch stop layer 170 are partially removed by performing planarization, and first and second gate masks 153 and 253 (FIG. 11) are removed to expose first dummy gate 152 and second dummy gate 252.

Next, the exposed first dummy gate 152 and second dummy gate 252 are removed by wet etching and/or dry etching. A first recess 155 may be formed in a region from which the first dummy gate 152 is removed, and a second recess 255 may be formed in a region from which the second dummy gate 252 is removed (as seen in FIG. 12).

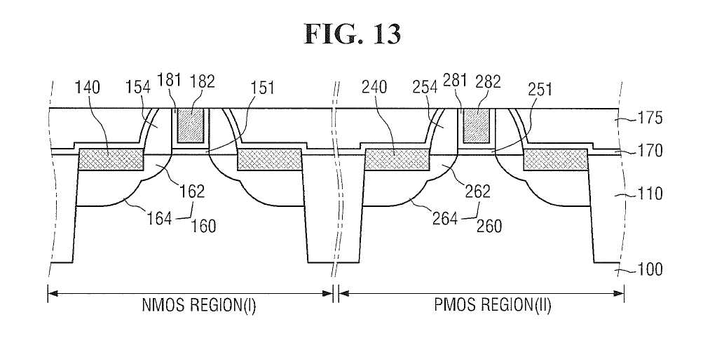

Referring next to FIGS. 12 and 13, first and second high-k layers 181 and 281 are conformally formed on bottom surfaces and opposing sidewalls of the first and second recesses 155 and 255, and a metal layer is buried on the first and second high-k layers 181 and 281, thereby forming first and second gates 182 and 282 (see FIG. 13). Accordingly, high-k metal gates may be formed on the device.

The first and second high-k layers 181 and 281 may be made of a high-k material such as HfO₂, ZrO₂, Al₂O₃, Ta₂O₅, hafnium silicate, zirconium silicate, or combinations thereof. The first and second gates 182 and 282 may be made of a metal such as Al, W, Ta, TaN, TaSiN, TiN, Mo, Ru, or Ni, or the material NiSi.

After the step of forming the first and second high-k layers 181 and 281, and before the step of forming the first and second gates 182 and 282, a third thermal process may further be performed in order to improve reliability of the first and second high-k layers 181 and 281. The third thermal process may be performed such that the device is heated to a temperature of 700° C. or higher. If such a third thermal process is performed, because the first and second metal silicide layers 140 and 240 have a film quality similar to that of a single crystal, layers 140 and 240 undergo little or no change in their morphologies.

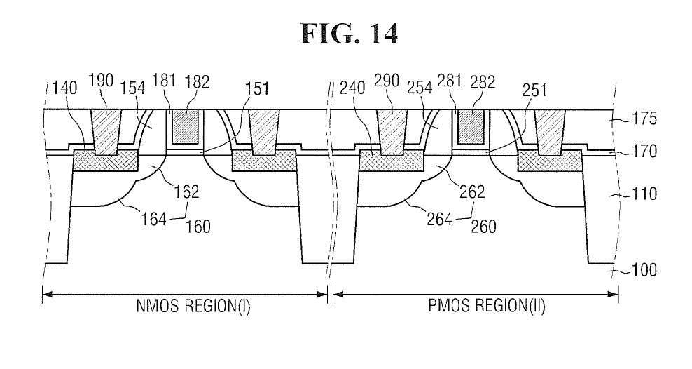

Referring next to FIG. 14, in the next fabrication step, contact holes are formed exposing the first and second metal silicide layers 140 and 240 by extending through the interlayer insulation layer 175 and the etch stop layer 170. A metallic material is then deposited to fill the contact holes, followed by performing a planarization process that forms first and second contacts 190 and 290 contacting, respectively, the first and second metal silicide layers 140 and 240. Subsequent fabrication processes on this device are the same as those of a general semiconductor manufacturing method, and thus a detailed description thereof will be omitted here.

In the foregoing description of FIGS. 7-14, the thermal process for activating the impurities implanted into the first source/drain regions 160 and the second source/drain regions 260 is performed before the step of forming of the metal layer 320 on the substrate 100 which has the first source/drain regions 160 and the second source/drain regions 260. However, in an alternative embodiment, the impurities implanted into the first source/drain regions 160 and the second source/drain regions 260 may be activated during the second thermal process sub-step 352. The second thermal process sub-step 352 is performed such that the layers 130 and 230 are heated to a temperature of about 1,000° C. or higher. Thus, the impurities in regions 160 and 260 can be activated by the steps of melting and subsequently quenching the first source/drain regions 160 and the second source/drain regions 260.

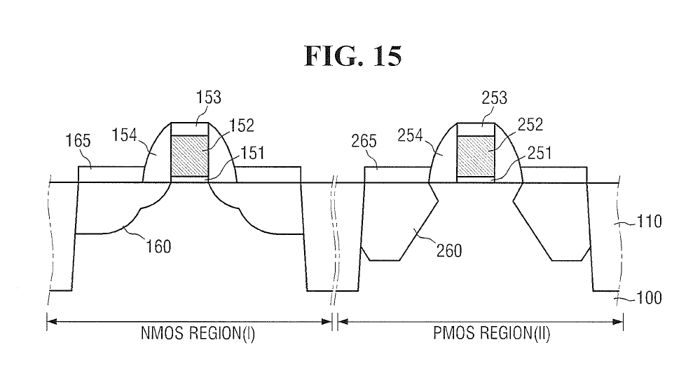

A method of fabricating a semiconductor device according to a second embodiment of the present inventive concept will now be described with reference to FIGS. 15 to 20. FIGS. 15 to 20 are schematic cross-sectional views illustrating steps in a method of fabricating a semiconductor device according to another embodiment of the present inventive concept.

The method of fabricating a semiconductor device according to the second embodiment of the present inventive concept is different from the previous embodiment in that epitaxial layers are formed in the first source/drain regions and the second source/drain regions. For convenience of explanation, the following description will focus on the differences, and substantially the same functional components as those of the previous embodiment will not be described again in detail or will be only briefly described as needed for clarity.

Referring to FIG. 15, a substrate 100 having an NMOS region (I), where an NMOS transistor is to be formed, and a PMOS region (II), where a PMOS transistor is to be formed, is provided. Isolation regions 110 may be formed to define and separate the NMOS region (I) and the PMOS region (II).

In the NMOS region (I) there are formed the following elements: a first gate insulation layer 151, a first dummy gate 152, a first gate mask 153, a first spacer 154, and first source/drain regions 160. in the PMOS region (II) there are formed the following elements: a second gate insulation layer 251, a second dummy gate 252, a second gate mask 253, a second spacer 254, and a second source/drain regions 260. The first dummy gate 152 and the second dummy gate 252 may be made of polysilicon.

A first epitaxial layer 165 rising toward or above a top portion of the substrate 100 is formed in the first source and drain regions 160.

For example, the first epitaxial layer 165 may be formed by a selective epitaxial growth process. The first epitaxial layer 165 advantageously improves the performance of an NMOS transistor to be subsequently formed on the NMOS region (I).

The selective epitaxial growth process may be performed by chemical vapor deposition (CVD), reduced pressure chemical vapor deposition (RPCVD), or ultra high vacuum chemical vapor deposition (UHVCVD), but the epitaxial growth process is not limited thereto.

The selective epitaxial growth process is performed by supplying a source gas. Examples of the source gas may include silane (SiH₄), dichlorosilane (DCS) (SiH₂Cl₂) trichlorosilane (TCS) (SiHCl₃), and so on. Additionally, when the selective epitaxial growth process is performed, not only the source gas but also a Cl-containing gas, such as HCl or Cl₂, may be supplied. By doing so, selectivity can be increased in the selective epitaxial growth process performed on the substrate 100.

A second epitaxial layer 265 may be formed in the second source/drain regions 260. The second epitaxial layer 265 may include SiGe. More specifically, in a case where the second epitaxial layer 265 is formed in a PMOS transistor that uses SiGe, a resulting stress may be applied to a channel region of the substrate due to a lattice length difference between Si atoms and Ge atoms. Such a stress applied to the channel region may increase hole mobility, and this increased hole mobility may improve the performance of the semiconductor device.

The second epitaxial layer 265 may be formed by an epitaxial growth process. The epitaxial growth process for forming the second epitaxial layer 265 may be performed at a temperature of approximately 500° C. to 900° C. and a pressure of about 1 to 500 Torr. The process conditions for the epitaxial growth process can be appropriately adjusted within the purpose and scope of the present invention. Examples of the silicon source gas may include, but are not limited to, SiH₄, SiH₂Cl₂, SiHCl₃, SiCl₄, SiHₓCl_{y} (x+y=4), Si(OC₄H₉)₄, Si(OCH₃)₄, and Si(OC₂H₅)₄. Examples of the Ge source gas may include, but are not limited to, GeH₄, GeCl₄, and GeHₓCl_{y} (x+y=4).

After implanting impurities into the first source/drain regions 160 and the second source/drain regions 260, a thermal process for activating the impurities may be performed.

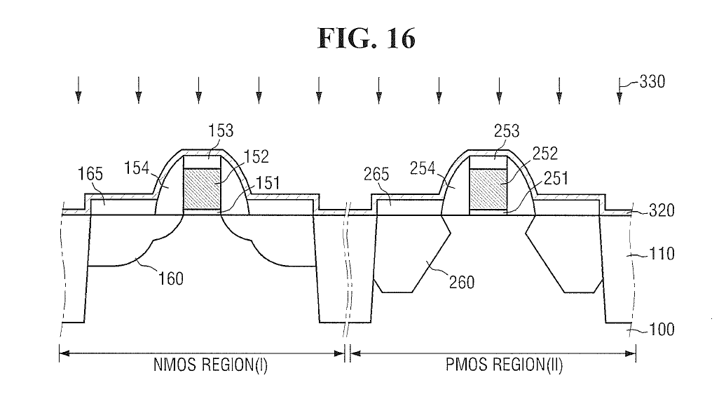

Referring now to FIG. 16, a metal layer 320 is formed on the semiconductor device of FIG. 15, which comprises the substrate 100 having the first epitaxial layer 165 and the second epitaxial layer 265. Next, the device of FIG. 16 is subjected to a first (lower-temperature) thermal process (as shown by the arrows 330).

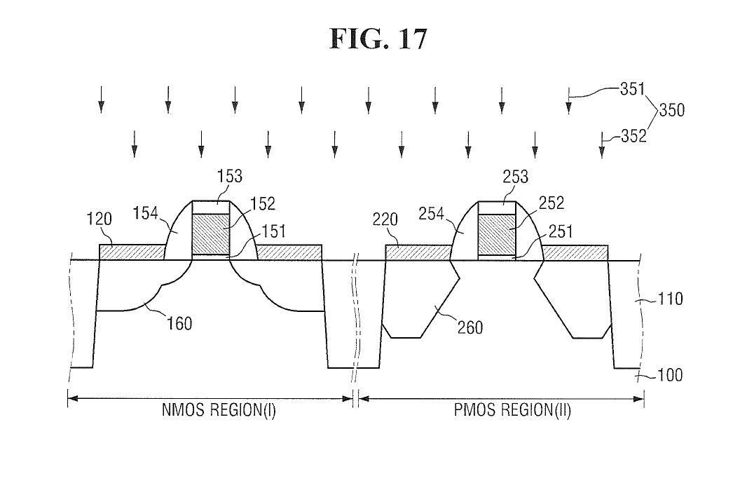

Referring to FIGS. 16 and 17, the first thermal process 330 is performed on the device of FIG. 16 for a sufficient time and at a sufficient temperature that the substrate 100 reacts with the metal layer 320 to form a first pre-metal silicide layer 120 in the NMOS region (I) and a third pre-metal silicide layer 220 in the PMOS region (II). The first pre-metal silicide layer 120 may be formed on the first epitaxial layer 165, and the third pre-metal silicide layer 220 may be formed on the second epitaxial layer 265 (as seen in FIG. 17).

Next, a portion of the metal layer 320 that has not reacted with the substrate 100 is removed. Here, if a metal oxide layer is formed in the course of this step, that metal oxide layer is also removed.

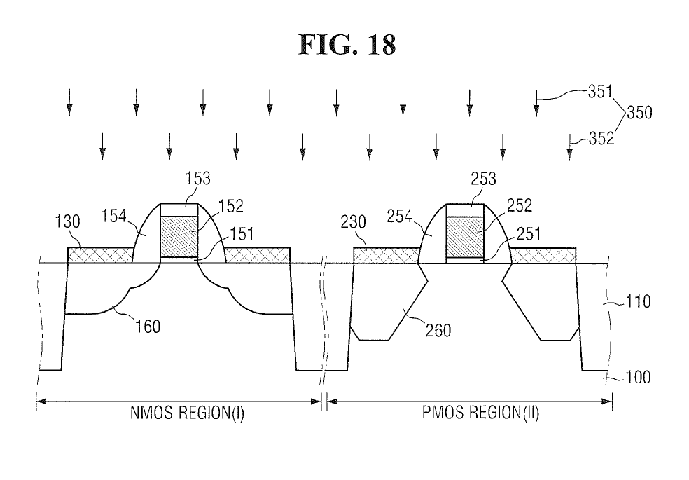

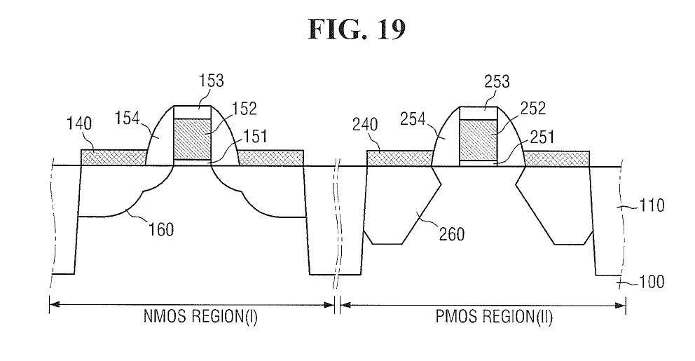

Referring now to FIGS. 17 to 19, a second (higher-temperature) thermal process 350 (as shown by the arrows 351 and 352 in FIGS. 17 and 18) is performed on the substrate 100 and the layers 120 and 220. The second thermal process 350 is performed for a sufficient time and at a sufficient temperature such that: (a) the first pre-metal silicide layer 120 (FIGS. 17 and 18) is changed, first into a second pre-metal silicide layer 130 (as seen in FIG. 18), and, subsequently, by continuing the thermal process 340, into a first metal silicide layer 140 (as seen in FIG. 19); and, (b) third pre-metal silicide layer 220 is changed, first into a fourth pre-metal silicide layer 230 (as seen in FIG. 18) and, subsequently, by continuing the thermal process 350, into a second metal silicide layer 240 (as seen in FIG. 19). As described above, the second (higher-temperature) thermal process 350 consists of two sub-steps: a first higher-temperature thermal process sub-step 351 and a second higher-temperature thermal process sub-step 352.

Atomic ratios of metal to silicon in the second and fourth pre-metal silicide layers 130 and 230 and in the first and second metal silicide layers 140 and 240 may preferably be equal to or less than 1. The first and second metal silicide layers 140 and 240 may be epitaxial layers, and they may have a film quality similar to that of a single crystal.

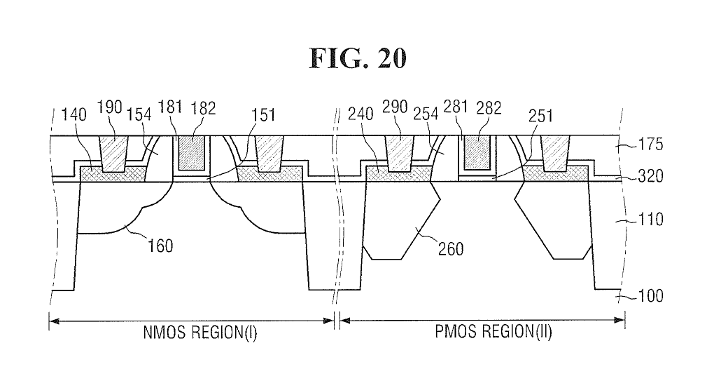

Referring next to FIG. 20, an etch stop layer 170, an interlayer insulation layer 175, first and second high-k layers 181 and 281, first and second gates 182 and 282, and first and second contacts 190 and 290 are formed respectively on the NMOS region (I) and on the PMOS region (II) through the processes shown in and previously described with reference to FIGS. 11 to 14.

In the foregoing description, the thermal process for activating the impurities implanted into the first source/drain regions 160 and the second source/drain regions 260 is performed on the substrate 100 having the first source/drain regions 160 and the second source/drain regions 260 before the step of forming of the metal layer 320 on the substrate 100 which has the first source/drain regions 160 and the second source/drain regions 260. However, in an alternative embodiment, the impurities implanted into the first source/drain regions 160 and the second source/drain regions 260 may also be activated during the second thermal process sub-step 352. The second thermal process sub-step 352 is performed such that the layers 130 and 230 are heated to a temperature of about 1,000° C. or higher. Thus, the impurities in regions 160 and 260 can be activated by the steps of melting and subsequently quenching the first source/drain regions 160 and the second source/drain regions 260.

While the present inventive concept has been particularly shown and described with reference to exemplary embodiments thereof, it will be understood by those of ordinary skill in the art that various changes in form and details may be made therein without departing from the spirit and scope of the present inventive concept as defined by the following claims. It is therefore desired that the present embodiments be considered in all respects as illustrative and not restrictive, reference being made to the appended claims rather than the foregoing description to indicate the scope of the inventive concept.

What is claimed is:

1. A method for fabricating a metal silicide layer comprising the steps of:
forming a metal layer on a substrate;
performing a lower-temperature thermal process on the substrate for a sufficient time and at a sufficient temperature that the substrate and the metal layer react with each other to form a first pre-metal silicide layer;
removing an unreacted portion of the metal layer; and
performing a higher-temperature thermal process on the first pre-metal silicide layer that changes the first pre-metal silicide layer first into a second pre-metal silicide layer, and then melts the second pre-metal silicide layer and changes the second pre-metal silicide layer into a metal silicide layer.

2. The method of claim 1, wherein an atomic ratio of metal to silicon in the first pre-metal silicide layer is greater than 1.

3. The method of claim 2, wherein atomic ratio of metal to silicon in the second pre-metal silicide layer and the atomic ratio of metal to silicon in the metal silicide layer are equal to or less than 1.

4. The method of claim 3, wherein the metal silicide layer is an epitaxial layer.

5. The method of claim 1, wherein the lower-temperature thermal process is carried out at a temperature lower than about 350° C.

6. The method of claim 5, wherein the higher-temperature thermal process comprises two sub-steps: a first higher-temperature thermal process sub-step carried out at a temperature of about 400° C. or higher; and, a second higher-temperature thermal process sub-step carried out at a temperature above the melting point of the second pre-metal silicide.

7. The method of claim 6, wherein the first higher-temperature thermal process sub-step and the second higher-temperature thermal process sub-step are performed in situ.

8. The method of claim 6, wherein a temperature of the second pre-metal silicide is increased to higher than 1,000° C. during the second higher-temperature thermal process sub-step.

9. The method of claim 6, wherein the lower-temperature thermal process is performed by a rapid thermal process (RTP), and the second higher-temperature thermal process sub-step is performed by flash annealing or laser annealing.

10. The method of claim 6, wherein the second higher-temperature thermal process sub-step is performed for a period of about 0.1 nano second to 10 milli seconds.

11. The method of claim 1, wherein the metal layer includes at least one member selected from the group consisting of Ni, Pt, Ti, Ru, Rh, Co, Hf, Ta, Er, Yb, W, and alloys thereof.

12. A method of fabricating a semiconductor device comprising the steps of
(a) forming a first gate on a substrate;
(b) implanting an impurity or impurities into source/drain regions in the substrate;
(c) forming a metal layer on the source/drain regions;
(d) forming a first pre-metal silicide layer by performing a lower-temperature thermal process on the substrate for a sufficient time and at a sufficient temperature that the substrate and the metal layer react to form a first pre-metal silicide layer;
(e) removing an unreacted portion of the metal layer; and
(f) changing the first pre-metal silicide layer into a second pre-metal silicide layer by performing a first higher-temperature thermal process sub-step on the first pre-metal silicide layer, and then changing the second pre-metal silicide layer into a metal silicide layer by melting the second pre-metal silicide layer during a second higher-temperature thermal process sub-step.

13. The method of claim 12, further comprising the step of performing another thermal process on the device to activate the impurity or impurities, wherein this additional thermal process is performed after step (b) but prior to step (c).

14. The method of claim 12, wherein during the second higher-temperature thermal process sub-step, the impurity or impurities implanted into the source/drain regions is/are activated.

15. The method of claim 12, further comprising the following additional steps after step (f):
(g) removing the first gate;
(h) forming a high-k layer on the substrate;
(i) forming a second gate on the high-k layer; and
(j) performing another thermal process on the substrate to improve reliability of the high-k layer.

16. The method of claim 15, wherein during step (j) the device is heated to a temperature of 700° or higher.

17. The method of claim 15, wherein the second gate of step (i) is made of a metal.

18. The method of claim 12, further comprising the step of forming an epitaxial layer in the source/drain regions.

19. The method of claim 12, wherein the lower-temperature thermal process is carried out at a temperature lower than about 350° C.

20. The method of claim 19, wherein the higher-temperature thermal process consists of a first higher-temperature thermal process sub-step in which the first pre-metal silicide layer is heated to a temperature of about 400° C. or higher, and a second higher-temperature thermal process sub-step in which a second pre-metal silicide layer formed by the first higher-temperature thermal process sub-step is heated to a temperature above a melting point of the second pre-metal silicide layer.
